(19) United States
(12) Patent Application Publication
(10) Pub. No.: US 2002/0045345 A1
(43) Pub. Date: Apr. 18, 2002

(54) ENHANCE PERFORMANCE OF COPPER DAMASCENE PROCESS BY EMBEDDING CONFORMAL TIN LAYER

(76) Inventors: CHIUNG-SHENG HSIUNG, HSIN-CHU CITY (TW); WEN-YI HSIEH, HSIN-CHU CITY (TW); WATER LUR, TAIPEI CITY (TW)

Correspondence Address: THOMAS T. MOGA, POWELL, GOLDSTEIN, FRAZER & MURPHY, LLP, 1001 PENNSYLVANIA AVE, N.W., SUITE 600, WASHINGTON, DC, 20004, US

(21) Appl. No.: 09/328,243

(22) Filed: Jun. 8, 1999

(51) Int. Cl. H01L 21/4763; H01L 21/44

(52) U.S. Cl. 438/687; 438/627; 438/628; 438/637; 438/643; 438/644

(57) ABSTRACT

A method that enhances performance of copper damascene by embedding TiN layer is proposed. The spirit of the invention is that a CVD TiN layer is inserted between the copper seed layer and the dielectric layer to improve the quality of copper layer. Herein, the TiN layer can either be located between the copper seed layer and the barrier layer or be located between the barrier layer and the dielectric layer. Because the barrier layer and the copper seed layer are formed by physical vapor deposition in current mass product, a higher side wall converge of the CVD TiN layer can be obtained owing to the higher conformity nature of CVD technology. Therefore, a better sidewall CVD TiN converge serves as an extra protection layer for copper self diffusion. Furthermore, it also acts as a copper seed layer to remedy side wall void problems due to copper seed layer discontinuity. Thus, not only the quality of copper layer is improved but also the performance of copper damascene process is enhanced.

### BACKGROUND OF THE INVENTION

1. Field of the Invention

The present invention relates to the enhancement of the copper damascene process, and more particularly to a method that enhances performance of barrier layer and copper seed layer by TiN layer.

2. Description of the Prior Art

Along with the advancement of semiconductor fabrication, ultra large semiconductor integration (ULSI) increasingly replaces very large semiconductor integration (VLSI) in many products and applications. Accompany with the trend, many useful fabrications of VLSI are outdated for ULSI and then it is desired to develop new fabrications.

An important example is that copper has become a promising candidate to replace aluminum for ULSI interconnections due to its better conductivity and reliability, which is more significant when the electromigration is more serious along with the decrement of width of interconnections.

No matter how, because there are many unsolved technical difficulties in copper etching process, the copper damascene process is widespread used to form copper interconnection by removing excess copper with chemical mechanical polish process.

The copper damascene process comprises following steps in sequence: forming a gap, forming a barrier layer, forming a copper seed layer, forming copper layer that completely fills the gap and removes excess copper layer. Where the barrier layer is used to prevent copper self diffusion and copper seed layer is used to aid growth of the copper layer.

In current fabrication of mass product, homely materials of barrier layer are TaN and Ta for excellent ability to prevent copper self diffusion. Beside, both barrier layer and copper seed layer are formed by physical vapor deposition (PVD) for better adhesion than chemical vapor deposition (CVD).

As shown in FIG. 1, when gap 12 is formed in dielectric layer 10, barrier layer 14 and copper seed layer 16 are formed on dielectric layer 10 in sequence by PVD. Obviously, because currently available PVD technologies for depositing barrier layer 14 and copper seed layer 16 result in poor sidewall coverage. It is undisputed that both barrier layer 14 and copper seed layer 16 are non-uniform in sidewall of gap 12, these non-uniformity's cause difficulties in copper process integration and induce higher risk and uncertainty in preventing copper self diffusion. Moreover, owing to the fact that growth of copper requires copper seed layer 16 and copper can not directly be plated on barrier layer 14, voids can occur on discontinued copper seed layer 16 and then performance of copper layer is degraded.

Thus, it is desired to develop a new fabrication to enhance performance of the barrier layer and the seed layer, which is reasonably important in copper damascene process to enhance performance of copper interconnections.

### SUMMARY OF THE INVENTION

Correspondingly, the primary object of the present invention is to propose a method that efficiently enhances performance of copper damascene process by embedding TiN layer.

A further object of the present invention is to propose a method that enhances performance of barrier layer and seed layer by inserting a TiN layer under the copper seed layer.

Moreover, a specific object is to improve non-uniformity of PVD TaN barrier layer and PVD copper seed layer by a CVD TiN layer, and more particularly to improve poor sidewall coverage of PVD layers by inserting a CVD TiN layer.

The spirit of the proposed invention is that inserts a CVD TiN layer between the PVD copper seed layer and the dielectric layer to improve the quality of copper layer. Herein, both the TiN layer and the barrier layer are located between the copper seed layer and the dielectric layer, and the relative position between the TiN layer and the barrier layer is convertible.

Because the barrier layer and the copper seed layer are formed generally by physical vapor deposition, a higher sidewall converge of the CVD TiN layer can be obtained owing to the higher conformity nature of CVD technology, and then can serve as an extra protection layer for copper self diffusion. Furthermore, because copper can directly grow on CVD TiN layer, CVD TiN layer can also act as an assistant copper seed layer to remedy sidewall void problems due to discontinuity of copper seed layer.

Therefore, it is obvious that the growth of copper layer is improved and the performance of copper damascene is enhanced.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 schematically illustrates a conventional barrier layer and copper seed stacks prior to copper formation;

FIG. 2A schematically illustrates an example of the proposed invention that a TiN layer is inserted between a barrier layer and a copper seed layer stacks before copper layer formation;

FIG. 2B schematically illustrates an example of the proposed invention that a TiN layer is inserted between a barrier layer and a copper seed layer stacks before copper layer formation; and

FIG. 3A to FIG. 3B shows how the growth of copper seed layer is improved by the TiN layer.

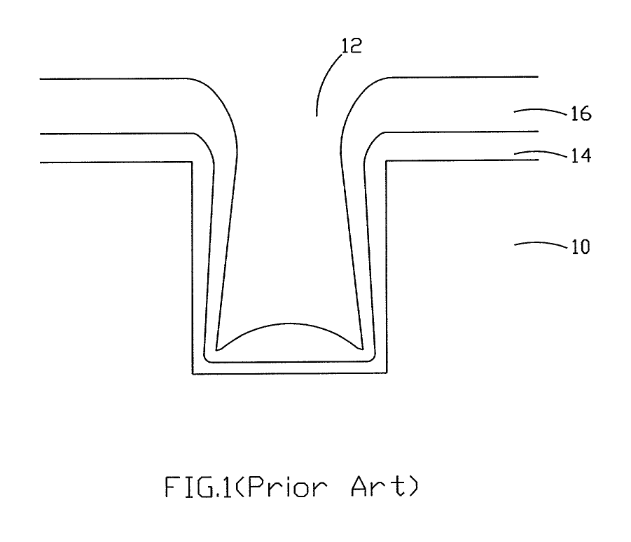

### DESCRIPTION OF THE PREFERRED EMBODIMENT

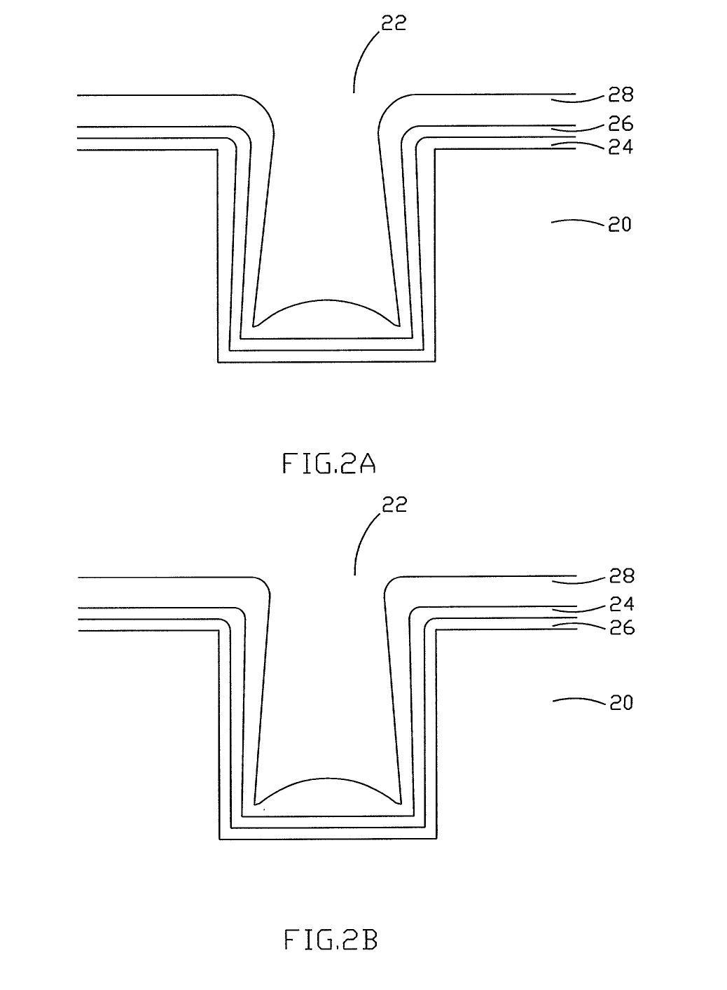

In order to illustrate the invention, a method of enhancing performance of PVD barrier layer and PVD copper seed layer by embedding conformal TiN layer is provided as an embodiment of the invention. The concept of the embodiment is illustrated by FIG. 2A and FIG. 2B.

FIG. 2A schematically illustrates the case that a conformal TiN layer is inserted between a barrier layer and a copper seed layer stacks before copper layer formation. Moreover, FIG. 2B schematically illustrates another case that a conformal TiN layer is inserted between a barrier layer and a dielectric layer stacks before copper layer formation.

The provided embodiment comprises following steps:

First, provides a substrate that comprises a plurality of structures such as metal oxide semiconductor (MOS), isolation and capacitor.

Second, covers the semiconductor substrate by dielectric layer 20. According to details of the semiconductor substrate, dielectric layer 20 may be an inter layer dielectric (ILD) or an inter metal dielectric (IMD) or other application.

Third, defines a plurality of locations on dielectric layer 20 that corresponding to a plurality of copper interconnections. Then, forms a plurality of gap windows 22 in these locations.

Fourth, forms barrier layer 24 and TiN layer 26 on dielectric layer 20. Where barrier layer 24 is formed by physical vapor deposition, and especially is formed by an ionized metal plasma physical vapor deposition (IMPPVD), but TiN layer 26 is formed by chemical vapor deposition. In addition, either TiN layer 26 formed on barrier layer 24 or barrier layer 24 formed on TiN layer 26 is acceptable for the proposed embodiment. Moreover, the material of barrier layer 24 must efficiently prevent copper inter diffusion and possible material of barrier layer 24 comprises Ta and TaN.

Fifth, forms copper seed layer 28 over barrier layer 24 and TiN layer 26, where copper seed layer 28 is formed by physical vapor deposition, and especially is formed by an ionized metal plasma physical vapor deposition.

Sixth, forms a copper layer on copper seed layer 28 and completely fills gap windows 22, where the copper layer is formed by electrochemical deposition (ECD) such as plating.

Finally, removes excess copper layer by a chemical mechanical polish process, and then a plurality of copper interconnections are formed.

Obviously, most details of the proposed method are similar to conventional copper damascene process expect a fundamental difference that CVD TiN layer 26 is employed.

Employment of CVD TiN layer 26 comprises three advantages:

First advantage, owing to the higher conformity nature of CVD technology, a higher side wall thickness coverage can be obtained in side wall of gap window 22. Thus, though side wall coverage of PVD barrier layer 22 is poor, but net side wall coverage of both barrier layer 24 and TiN layer 26 is excellent. Therefore, excellent side wall coverage of TiN layer 26 can serve as an extra protection layer for copper self diffusion. On the other word, for any point of side wall of gap window 22 that thickness of barrier layer 24 is thin, the protection of copper self diffusion is enhanced by CVD TiN layer 26. Obviously, the net protection is independent on either barrier layer 24 is formed on TiN layer 26 or TiN layer 26 is formed on barrier layer 24.

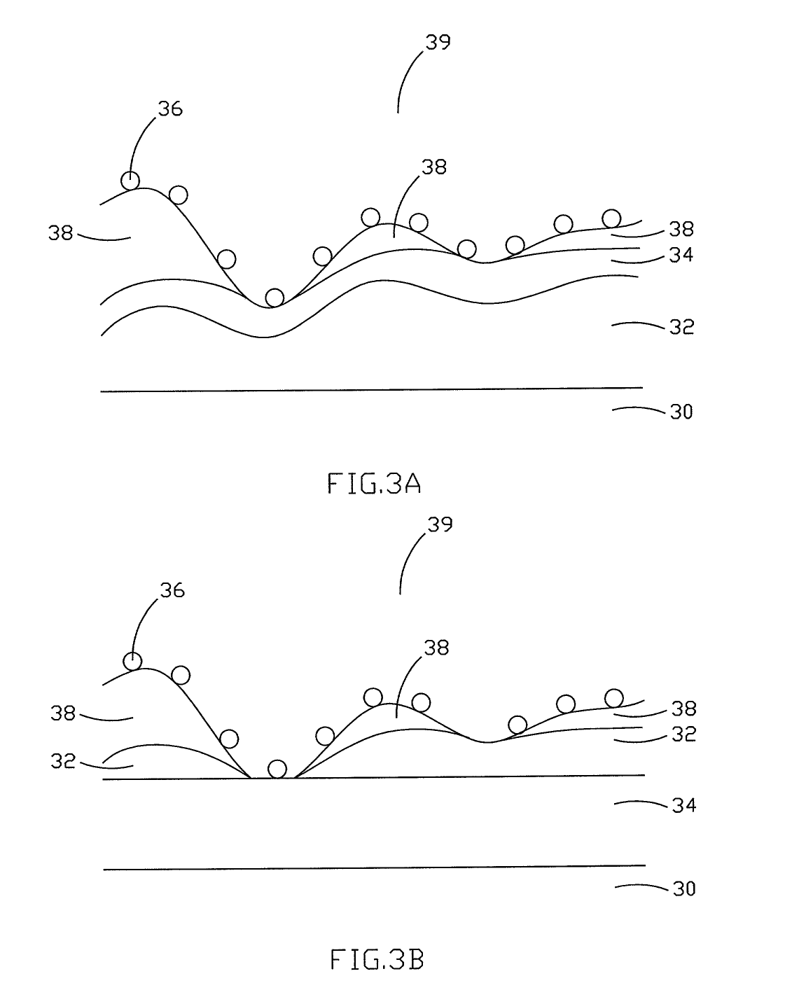

Second advantage, because copper can not be plated on material of barrier layer 24 such as Ta and TaN but it can be plated on CVD TiN, CVD TiN layer 26 can act as an equivalent copper seed layer for copper ECD. Thus, though copper seed layer 28 is formed by PVD and there are some discontinuities, but side wall void problems that induced by these discontinuities are improved by TiN layer 26. FIG. 3A and FIG. 3B illustrate the mechanism of the improvement.

Referring to FIG. 3A, PVD barrier layer 32 is formed on dielectric layer 30 and CVD TiN layer 34 is formed on PVD barrier layer 32, then copper seed layer 38 is formed on CVD TiN layer 34. Obviously, total surface of CVD TiN layer 34 is beneficial to form plated copper 36 and then side wall void problems that induced by discontinuity 39 of copper seed layer 38 are improved.

In comparison, referring to FIG. 3B, where CVD TiN layer 34 is formed on dielectric layer 30 and PVD barrier layer 32 is formed over CVD TiN layer 34, then copper seed layer 38 is formed on PVD barrier layer 32. It is obvious that PVD barrier layer is non-uniform and then copper seed layer 38 that formed on barrier layer 32 is more non-uniform and there are some discontinuities 39. No matter how, because copper can be plated on CVD TiN, TiN layer 34 can act as an equivalent seed layer for copper ECD and thus remedies side wall void problems.

Moreover, it is always possible that there are discontinuities 39 due to non-uniformity of PVD process. When discontinuities 39 of copper seed layer 38 corresponds to TiN layer 34, the uniformity of copper layer is not degraded by discontinuities 39 for copper can be plated on both copper seed layer 38 and TiN layer 34. In comparison, when discontinuities 39 of copper seed layer 38 corresponds to barrier layer 32, the uniformity of copper layer is degraded by discontinuities 39 for copper can only be plated on copper seed layer 38 but can not be plated on barrier layer 32. In other words, to enhance quality of copper layer, it is better that TiN layer 34 is formed on barrier layer 32.

Third advantage, because conformal CVD TiN layer 26 may decrease required thickness of barrier layer 24 to stop copper self diffusion and decrease required thickness of copper seed layer 28 to achieve void-free copper ECD. The re-entrant effect on copper ECD is reduced by decreasing required copper seed layer thickness 28. Thus, CVD TiN layer 26 may increase process window of copper damascene and enhance performance of copper interconnections. Herein, for thickness of barrier layer 24 is about less than 400 Å, thickness of said copper seed layer is not larger than about 3000 Å and thickness of TiN layer 26 is about 100 Å to 200 Å.

While the invention has been described by way of example and in terms of preferred embodiment, the invention is not limited there to. To the contrary, it is intended to cover various modifications, procedures and products, and the scope of the appended claims therefore should be accorded to the broadest interpretation so as to encompass all such modifications and similar arrangement, procedures and products.

What is claimed is:

1. A method that enhances performance of PVD barrier layer and PVD copper seed layer by embedding a conformal TiN layer, said method comprising:
providing a substrate, wherein said semiconductor substrate comprises a plurality of structures;
covering said semiconductor substrate by a dielectric layer;
defining a plurality of locations on said dielectric layer that corresponding to a plurality of copper interconnections;
forming a plurality of gap windows in said locations;
forming a barrier layer and a TiN layer over said dielectric layer;
forming a copper seed layer over said barrier layer and said TiN layer;
forming a copper layer on said copper seed layer, said copper layer completely filling said gaps; and
removing excess copper layer by a chemical mechanical polish process.

2. The method according to claim 1, wherein said structures comprises MOS, isolation and capacitor.

3. The method according to claim 1, wherein said barrier layer is formed by a physical vapor deposition, and especially is formed by an ionized metal plasma physical vapor deposition.

4. The method according to claim 1, wherein material of said barrier layer comprises TaN and Ta.

5. The method according to claim 1, wherein thickness of said barrier layer is less than about 400 Å.

6. The method according to claim 1, wherein said conformal TiN layer is formed by a chemical vapor deposition.

7. The method according to claim 1, wherein thickness of said TiN layer is about 100 Å to 200 Å.

8. The method according to claim 1, wherein formation of said barrier layer and said TiN layer can be performed in two sequences, one is forming said barrier layer on said TiN layer and the other is forming said TiN layer on said barrier layer.

9. The method according to claim 1, wherein said copper seed layer is formed by a physical vapor deposition, and especially is formed by an ionized metal plasma physical vapor deposition.

10. The method according to claim 1, wherein thickness of said copper seed layer is not larger than about 3000 Å.

11. The method according to claim 1, wherein formation of said copper layer comprises plating.

12. A method that enhances capabilities and process window for TaN barrier layer and copper seed layer by inserting a TiN layer, said method comprising:
forming a dielectric layer, said dielectric layer comprises an inter-layer dielectric layer and an inter-metal dielectric layer;
patterning a plurality of gap windows on said dielectric layer;
depositing a TaN barrier layer on said dielectric layer;
depositing a TiN layer on said TaN layer;
sputtering a copper seed layer on said TiN layer;
forming a copper layer on said copper seed layer and completely filling said gap windows; and
removing excess copper layer.

13. The method according to claim 12, wherein said TaN layer is formed by an ionized metal plasma physical vapor deposition.

14. The method according to claim 12, wherein said TiN layer is formed by a chemical vapor deposition.

15. The method according to claim 12, wherein thickness of said copper seed layer is about 1000 Å to 2000 Å.

16. The method according to claim 12, wherein said copper layer is formed by an electrochemical deposition.

17. The method according to claim 12, wherein remove of said excess copper layer is provided by a chemical mechanical polish process.
